(19) United States
(12) Patent Application Publication
(10) Pub. No.: US 2016/0273097 A1
(43) Pub. Date: Sep. 22, 2016

(54) METHOD FOR MONITORING SE VAPOR IN VACUUM REACTOR APPARATUS

(71) Applicant: NUVOSUN, INC., Milpitas, CA (US)

(72) Inventors: Arthur C. WALL, Morgan Hill, CA (US); Sam KAO, Los Altos, CA (US); John Kwangyong KIM, San Jose, CA (US); Bruce D. HACHTMANN, San Martin, CA (US); Qiongzhong JIANG, Saratoga, CA (US); Karnig Ross Baron PORTER, Cambridge, MA (US)

(73) Assignee: NUVOSUN, INC., Milpitas, CA (US)

(21) Appl. No.: 15/035,227

(22) PCT Filed: Oct. 16, 2014
(86) PCT No.: PCT/US2014/060832

§ 371 Date: May 7, 2016

Related U.S. Application Data
(60) Provisional application No. 61/905,175, filed on Nov. 16, 2013.

(51) Int. Cl. C23C 14/54; C23C 14/24; C23C 14/06

(52) U.S. Cl. CPC C23C 14/546; C23C 14/0623; C23C 14/243; C23C 14/543

(57) ABSTRACT

Methods and systems are disclosed for monitoring vapor in a vacuum reactor apparatus. An system has (a) a vacuum chamber, (b) a vapor source housed in the vacuum chamber, wherein the vapor source is configured to generate a vapor, (c) a reaction vessel housed in the vacuum chamber and coupled to the vapor source, where the reaction vessel has an outlet to the vacuum chamber, and where the reaction vessel is configured to receive the vapor from the vapor source and to emit a portion of the received vapor into the vacuum chamber through the outlet, and (d) one or more sensors housed in the vacuum chamber, where the one or more sensors are configured to detect the vapor emitted through the outlet.

### CROSS-REFERENCE TO RELATED APPLICATION

This application claims prior to U.S. Provisional Application No. 61/905,175 filed Nov. 16, 2013, which is hereby incorporated by reference in its entirety.

### BACKGROUND

Unless otherwise indicated herein, the materials described in this section are not prior art to the claims in this application and are not admitted to be prior art by inclusion in this section.

Systems for monitoring vapor pressure in a reactor chamber are utilized during application of vapor (e.g., selenium) to a substrate to make, for example, thin film solar cells. typical reactor chambers include a vacuum chamber, a vapor source and a reaction vessel. Some conventional systems monitor vapor at the vapor source to control the temperature of the vapor source. The combination of the thermal mass of the vapor source and the nature of the reacting selenium, for example, can cause the temperature to change. Try slowly in response to control feedback. In addition, any perturbation in the actual reaction in the reaction vessel due to differences in the reacting samples or variation due to leaking between the reaction vessel and the vacuum chamber are not accounted for. Further, current systems are expensive, prone to failure and cannot operate for the duration of time needed or at the high operating temperatures present in a manufacturing environment.

### SUMMARY

Example embodiments provide a vapor monitoring system and methods configured to direct a stream of vapor from a high pressure zone in a reaction vessel to a lower pressure zone in a vacuum chamber and to detect vapor by a sensor. This arrangement advantageously provides feedback correlated to the amount of vapor in the reaction vessel. The system further beneficially provides a valve to immediately control the rate of transfer of vapor from the vapor source to the reaction vessel to maintain a constant amount of vapor in the reaction vessel. In addition, in embodiments employing an ion gauge or selenium rate monitor, the sensor has the advantages of being less temperature sensitive than other sensors and detects ion presence rather than being coated with the vapor material to measure weight, which results in fewer replacement parts and an increased longevity of the sensor.

Thus, in one aspect, a system is provided having (a) a vacuum chamber, (b) a vapor source housed in the vacuum chamber, wherein the vapor source is configured to generate a vapor, (c) a reaction vessel housed in the vacuum chamber and coupled to the vapor source, where the reaction vessel has an outlet to the vacuum chamber, and where the reaction vessel is configured to receive the vapor from the vapor source and to emit a portion of the received vapor into the vacuum chamber through the outlet, and (d) one or more sensors housed in the vacuum chamber, where the one or more sensors are configured to detect the vapor emitted through the outlet.

In another aspect, a method is provided including the steps of (a) transferring, through a valve, a vapor from a high pressure zone to a medium pressure zone, (b) emitting, through an outlet, a portion of the transferred vapor from the medium pressure zone to a low pressure zone, and (c) detecting, by a sensor in the low pressure zone, the vapor emitted through the outlet.

These as well as other aspects, advantages, and alternatives, will become apparent to those of ordinary skill in the art by reading the following detailed description, with reference where appropriate to the accompanying drawings.

### BRIEF DESCRIPTION OF THE DRAWINGS

FIG. 1 is a schematic view of the system for monitoring vapor in a vacuum reactor apparatus, in accordance with an example embodiment.

FIG. 2A is an elevational front view of an example embodiment of the system for monitoring vapor utilizing a microbalance sensor.

FIG. 2B is a cross-sectional side view of the system for monitoring vapor of FIG. 2A.

FIG. 3A is an devotional front view of an example embodiment of the system for monitoring vapor utilizing an ion gauge sensor or selenium rate monitor sensor (“SRM”) and two additional microbalance sensors offset from the outlet and the path of the emitted vapor stream.

FIG. 3B is a cross-sectional side view of the system for monitoring vapor of FIG. 3A.

FIG. 4A is an elevational front view of an example embodiment of the system for monitoring vapor utilizing two ion gauges or SRM sensors.

FIG. 4B is a cross-sectional top view of the system for monitoring vapor of FIG. 4A.

FIG. 4C is a cross-sectional side view of the system for monitoring vapor of FIG. 4C.

FIG. 5 is a graph showing a microbalance sensor's response relative to the rate of transfer of selenium vapor from a vapor source to a reaction vessel, in accordance with an example embodiment.

FIG. 6 is a graph showing an ion gauge's response relative to the rate of transfer of selenium vapor from a vapor source to a reaction vessel, in accordance with an example embodiment.

FIG. 7 is a method according to an example embodiment.

### DETAILED DESCRIPTION

Example methods and systems are described herein. Any example embodiment or feature described herein is not necessarily to b construed as preferred or advantageous over other embodiments or features. The example embodiments described herein are not meant to be limiting. It will be readily understood that certain aspects of the disclosed systems and methods can be arranged and combined in a wide variety of different configurations, all of which are contemplated herein.

Furthermore, the particular arrangements shown in the Figures should not be viewed as limiting. It should be understood that other embodiments may include more or less of each element shown in a given Figure. Further, some of the illustrated elements may be combined or omitted. Yet further, an example embodiment may include elements that are not illustrated in the Figures.

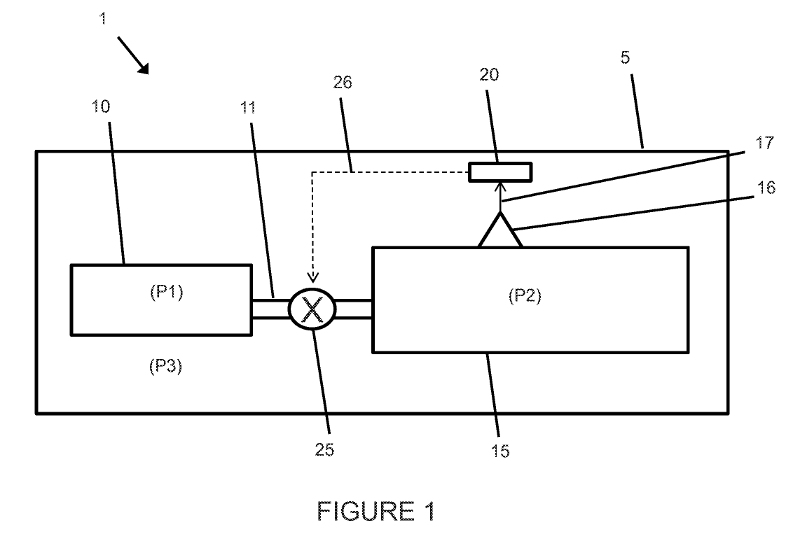

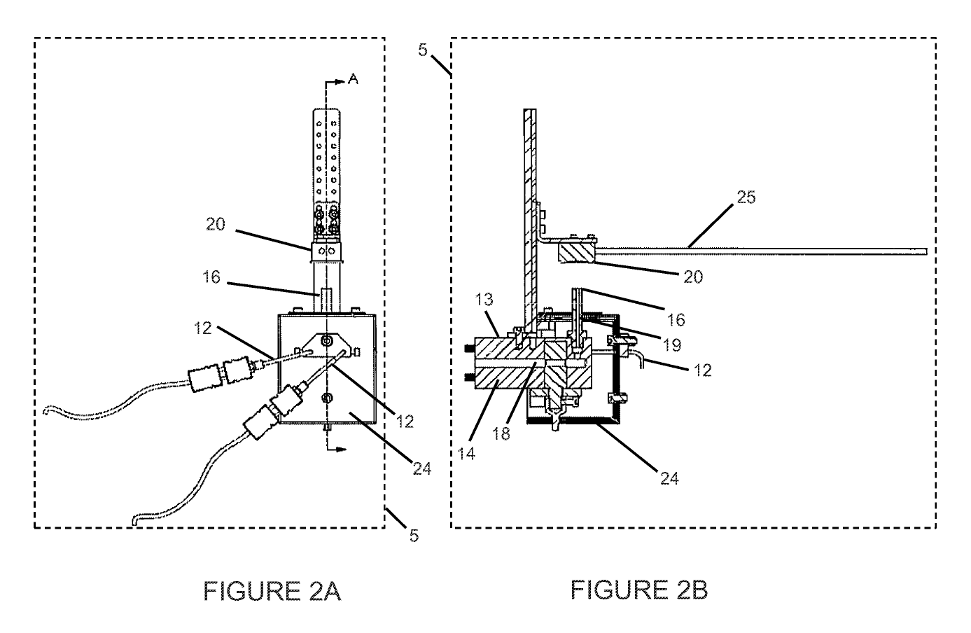

The present embodiments advantageously provide a system for monitoring and controlling vapor emitted from a high pressure zone to a low pressure zone. Referring now to FIGS. 1-2B, a system is shown having a vacuum chamber 5. A vapor source 10 is housed in the vacuum chamber 5. The vapor source 10 is configured to generate a vapor. In some embodiments, the vapor source 10 comprises a crucible, and the vapor is generated via one or more heating elements that increase the temperature of the vapor source 10 to cause evaporation of a vacuum-compatible material. The operating temperature at the vapor source 10 is maintained in the range from about 250° C. to about 450° C. and is preferably in the range of 300° C. to about 370° C. In various embodiments, organic and inorganic vacuum-compatible materials may be used as the vapor for deposition applications, for example. In a preferred embodiment, the vapor comprises selenium. In various other embodiments, the vapor may comprise sulfur or other evaporable selenium- or sulfur-containing compounds, for example.

A reaction vessel 15 is likewise housed in the vacuum chamber 5 and is coupled to the vapor source 10 via a conduit 11. The reaction vessel 15 defines a chamber capable of housing a substrate for roll-to-roll processing, for example. In various embodiments, the conduit 11 comprises a tube or any other passage. The reaction vessel 15 and the conduit 11 each comprise any material capable of withstanding the foregoing operating temperatures and selenium vapor, e.g. stainless steel. In some embodiments, the reaction vessel 15 and the conduit 11 may be independently heated to maintain the desired operating temperature.

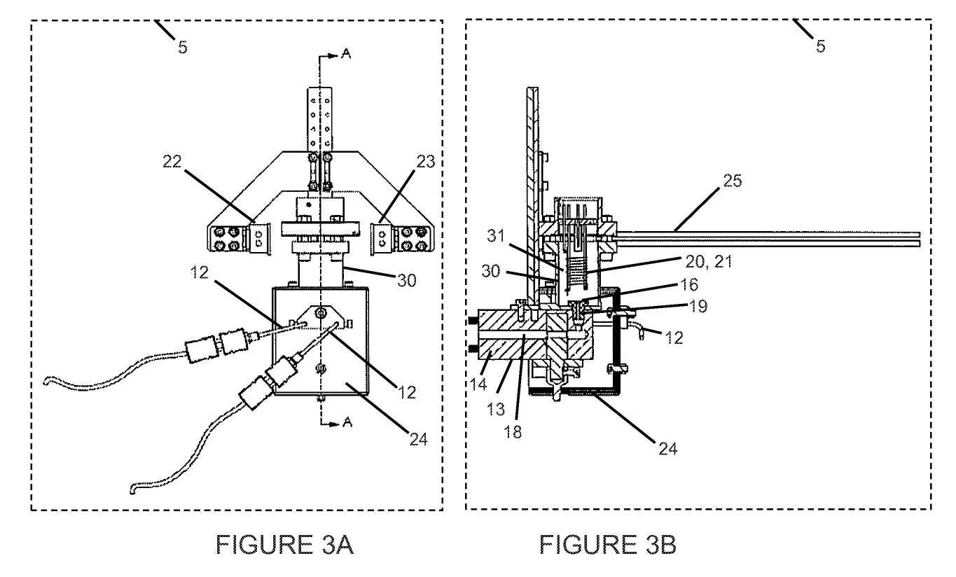

The reaction vessel 15 has an outlet 16 to the vacuum chamber 5. The reaction vessel 15 is further configured to receive the vapor from the vapor source 10 and to emit a portion 17 of the received vapor into the vacuum chamber 5 through the outlet 16. In some embodiments, the outlet 16 may comprise an opening in direct communication with the chamber of the reaction vessel 15. In alternative embodiments, the reaction vessel 15 may further comprise a tunnel 18, as shown in FIGS. 28, 3B and 4B, that couples the chamber of the reaction vessel 15 to the outlet 16, where the tunnel 18 has a diameter that is larger than the diameter of the outlet 16. In these embodiments, the reaction vessel 15 maintains a high temperature in the chamber of the reaction vessel 15. The reaction vessel 15 further includes a housing 13 defining a region 14 that has a temperature controlled independently from that of the chamber via, for example, thermal couples 12. In these embodiments, tunnel 18 and the outlet 16 are defined in region 14 of the reaction vessel housing 13 and both are at least partially contained within a radiation shield 24. The tunnel 18 provides an intermediate path that directs the vapor from the chamber of the reaction vessel 15 to the outlet 16. In some embodiments, the outlet 16 itself may comprise an elongated conduit 19, as opposed to a basic opening.

In one embodiment, the vapor source 10 has a first pressure P1, the reaction vessel 15 has a second pressure P2, and the vacuum chamber 5 has a third pressure P3. In various embodiments, the first pressure P1 is greater than the second pressure P2 and the second pressure P2 is greater than the third pressure P3. The first pressure may range from about 10⁺¹ to about 10⁻² the second pressure may range from about 10⁻² to about 10⁻⁴, and the third pressure may range from about 10⁻⁴ to about 10⁻⁶. Due to the nature of the vapor, the vapor flows from the high pressure zone P1 in the vapor source 10 to the medium pressure zone P2 in the reactor vessel 15 to a low pressure zone P3 in the vacuum chamber 5. The respective pressures are a factor of the temperature of the vapor source 10, the reaction vessel 15 and the vacuum chamber 5. as well as the vacuum pressure applied directly the vacuum chamber 5 to maintain the desired pressure P3.

One or more sensors 20 are housed in the vacuum chamber 5, The one or more sensors 20 is configured to detect the vapor 17 emitted through the outlet 16. In a preferred embodiment, the vapor 17 is emitted in a stream and the sensor 20 is positioned directly in the path of the stream or in the vicinity of the stream. In another preferred embodiment, the outlet 16 is positioned on a top surface of the reactor vessel 15, but the outlet could be positioned on a side of the reactor vessel 15 to achieve the same results.

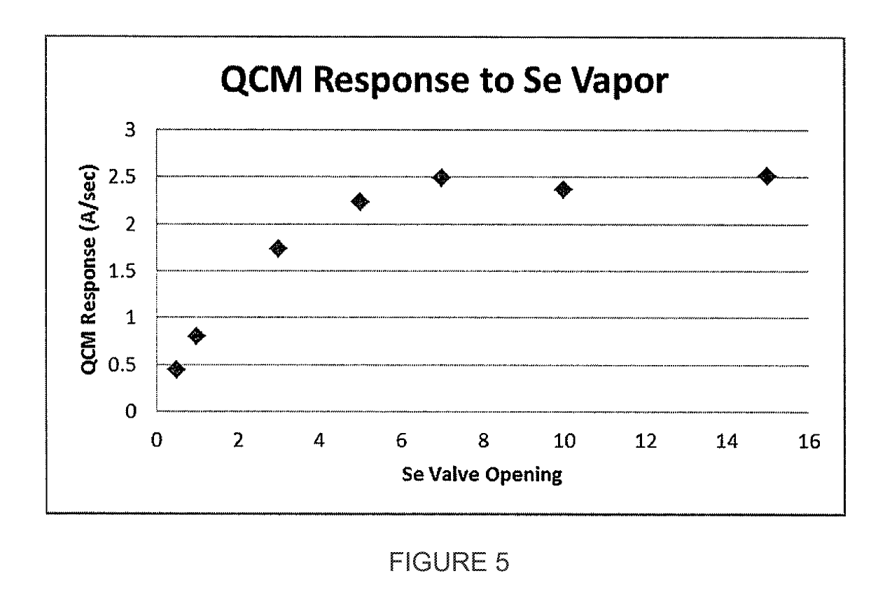

In various embodiments, the sensor may comprise a microbalance (FIGS. 2A-B and 3A-3B), an ion gauge, otherwise referred to as a selenium rate monitor (SRM) (FIGS. 3A-B, 4A-C) or a combination of the two (FIGS. 3A-B, 4A-C). Microbalances are instruments configured to measure the weight of condensing particles having very small mass, i.e., on the order of a million parts of a gram. The microbalances may include quartz crystal microbalances (“QCM”), which are sensitive mass deposition sensors that rely upon the piezoelectric properties of quartz crystal. QCMs utilize changes in resonance frequency of the crystal to measure the mass on the surface of the sensor, since resonance frequency is highly dependent on any changes of the crystal mass. QCMs are capable of measuring mass deposition as small as 0.1 nanograms. FIG. 5 shows that the flow rate of the vapor increases, as a valve 25 (discussed below) opens, and that the vapor density registered by a QCM also increases. Since QCMs measure the amount of material or weight that is condensing on the quartz crystal surface. The sensor operates based on the presumption that the material is depositing evenly, translating the amount or weight into the equivalent thickness for a thin film, where A/second represents angstroms or 10⁻¹⁰ m of thickness.

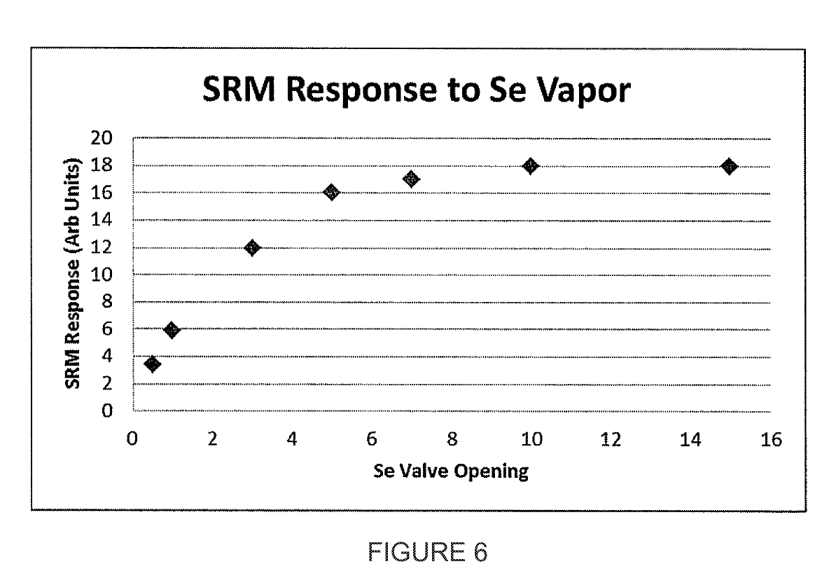

Ion gauges and selenium rate monitors (“SRM”) are each configured to be used in a low-pressure (vacuum) environment. Ion gauges and SRMs sense pressure indirectly by measuring the electrical ions produced when the vapor is bombarded with electrons, where fewer ions will be produced by lower density vapors. There are two primary types of ion gauges, namely hot cathode and cold cathode. In operation, the hot cathode gauge includes an electrically heated filament used to generate an electron beam. The electrons travel through the gauge and ionize surrounding vapor molecules. These resulting ions are then collected at a negative electrode. The current generated corresponds to the number of ions, and the number of ions in turn corresponds to the vapor pressure registered by the gauge. Hot cathode gauges are accurate from about 10⁻³ Ton to about 10¹⁰ Torr. Cold cathode gauges operate in a similar manner, the difference being that electrons are produced via discharge of a high voltage. Cold cathode gauges are accurate from about 10⁻² Torr to about 10⁻⁹ Torr. FIG. 6 shows that as the valve 25 opens the flow rate of the vapor increases and the vapor density registered by a SRM also increases, where the arbitrary units represent pressure divided by 10⁻⁴ torr.

In one embodiment, shown in FIGS. 2A-B, the one or more sensors 20 comprises a single microbalance positioned directly over the outlet 16. In this arrangement, the outlet 16 is configured as a conduit 19 or tube having an inner diameter that may range from about 0.1 cm to about 0.5 cm and may extend from about 2 cm to about 5 cm from the reactor vessel 15. The microbalance may be positioned from about 0.5 cm to about 1.5 cm from the outlet 16 in order to obtain accurate measurements. In one embodiment, cooling water lines 25 may be coupled to the microbalance 20.

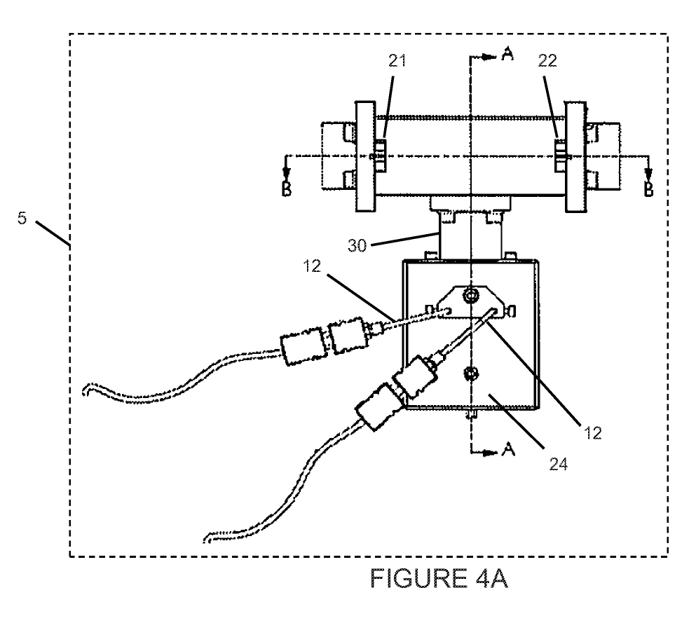

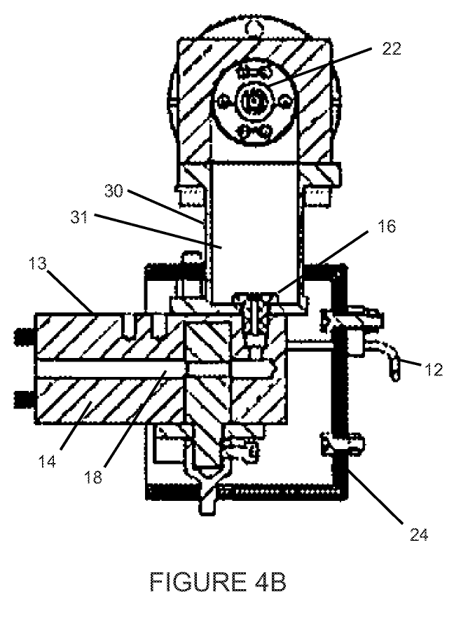

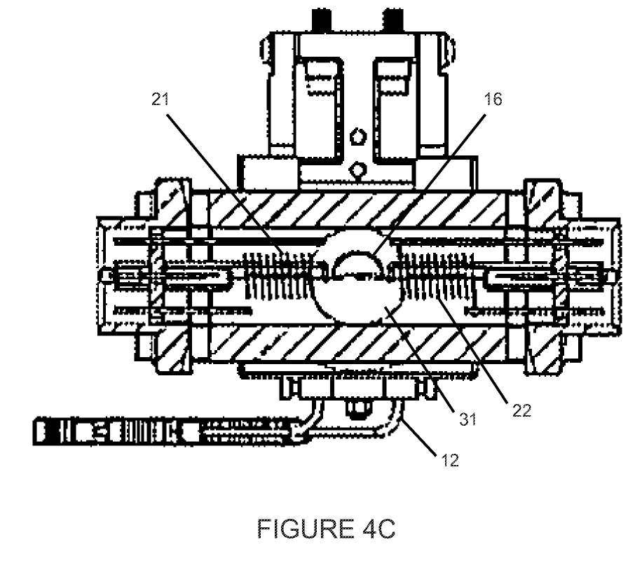

In another embodiment, shown in FIGS. 3A-B and 4A-C, the one or more sensors comprises a first sensor and a second sensor each housed in the vacuum chamber 5. In one example embodiment, shown in FIGS. 4A-C, the first sensor 21 and the second sensor 22 are each offset from the outlet 16 and from the direct path of the emitted vapor stream 17. The opening of the outlet 16 is configured in the form of a nozzle that is substantially recessed within the reactor vessel. The outlet nozzle 16 disperses the stream into a column 30, for example, that defines a channel 31 in communication with the first and second sensors 21, 22. Channel 31 is configured to contain most of the vapor emitted from outlet 16. Channel 31 defines a differential pressure zone that is read by one or more ion gauges. In some embodiments, a vacuum nipple is of sufficient diameter to house an ion gauge. In this arrangement, the first and second sensors 21, 22 are ion gauges or selenium rate monitors arranged on opposing sides of the channel 31. The second sensor 22 may be used to confirm the results of the first sensor 21, for example.

In another example embodiment, shown in FIGS. 3A-B, a third sensor 23 is provided, such that the first sensor 21 is positioned directly over the outlet 16, while the second sensor 22 and third sensor 23 are offset from the outlet 16. In this arrangement, the first sensor 21 is an ion gauge or selenium rate monitor and the second and third sensors 22, 23 are microbalances. Like the embodiment shown in FIGS. 4A-C, the opening of the outlet 16 is again configured in the form of a nozzle that disperses the vapor stream into a column 30, for example, that defines a channel 31 in communication with the first sensor 21. The second and third sensors 22, 23 are disposed on opposing sides of the column 30 and vapor is directed onto the microbalances via outlets (not shown) defined in either side of column 30 and in communication with channel 31. These second and third sensors 22, 23 may be used to confirm the results of the first sensor 21, for example.

In one embodiment, the system 1 includes a valve 25 configured to control an amount of the vapor received by the reaction vessel 15 from the vapor source 10. In various embodiments, the valve 25 is disposed between the vapor source 10 and the reactor vessel 15, preferably at a location along conduit 11, Alternatively, the valve may be positioned at the vapor outlet on the vapor source 10 or at the vapor inlet on the reactor vessel 15. The valve 25 controls the amount of vapor through opening and/or closing action, either partially or completely, depending on the circumstances. In a further embodiment, the valve 25 is configured to control the amount of the vapor in response to one or more control signals 26. These control signals 26 may be generated by a controller in communication with the one or more sensors 20 and the valve 25. The controller may include a processor and memory to analyze control signals or feedback 26 from the one or more sensors 20 and to determine the adjustments, if any, to be made at the valve 25. In various embodiments, the controller is capable of processing feedback or control signals 26 from multiple sensors 21, 22, and/or 23 and determining whether a sensor needs to be calibrated or replaced. In some embodiments, an operator of the system may be able to provide manual override instructions to the controller via a control panel, keyboard or other input device.

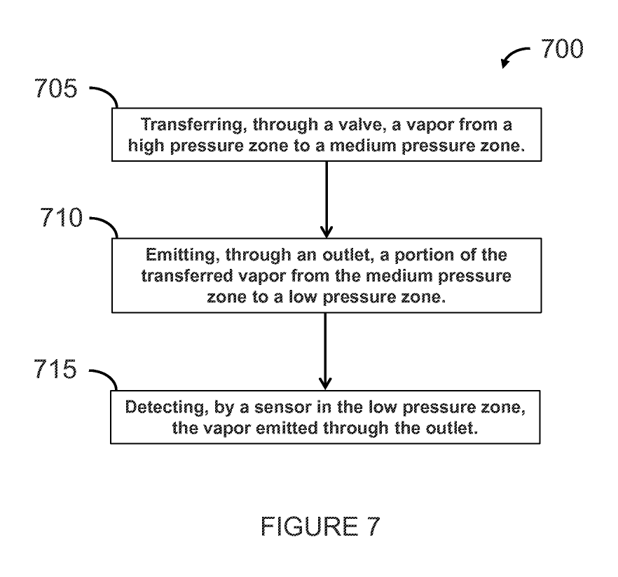

FIG. 7 is a flow chart of a method 700 that is provided that includes the step 705 of transferring, through a valve 25, a vapor from a high pressure zone P1 to a medium pressure zone P2. Method 700 further includes the step 710 of emitting, through an outlet 16, a portion 17 of the transferred vapor from the medium pressure zone P2 to a low pressure zone P3 in a vacuum chamber 5. Method 700 also includes the step 715 of detecting, by a sensor 20, 21 in the low pressure zone P1, the vapor 17 emitted through the outlet 16. In various other embodiments, the method may further include the steps of detecting, by a second sensor 22 in the low pressure zone P3, the vapor emitted through the outlet 16, and detecting, by a third sensor 23 in the low pressure zone P3, the vapor emitted through the outlet 16.

In some embodiments, method 700 further includes the step of developing a control signal, based on the vapor 17 detected by the sensor 20, as well as the step of controlling the valve 25 based on the control signal 26. In various embodiments, controlling the valve 25 based on the control signal 26 comprises controlling orate of transfer of the vapor from the high pressure zone P1 to the medium pressure zone P2. In further other embodiments, method 700 also includes the steps of generating the vapor in the high pressure zone P1, generally located in the vapor source 10, and reacting the vapor in the medium pressure zone P2, generally located in the reactor vessel 15. The method may be performed using any of the embodiments of the system described above.

The above detailed description describes various features and functions of the disclosed systems and methods with reference to the accompanying figures. While various aspects and embodiments have been disclosed herein, other aspects and embodiment: be apparent to those skilled in the art. The, various aspects and embodiments disclosed herein are for purposes of illustration and are not intended to be limiting, with the true scope and spirit being indicated by the following claims.

1. A system, comprising:
a vacuum chamber;
a vapor source housed in the vacuum chamber, wherein the vapor source is configured to generate a vapor;
a reaction vessel housed in the vacuum chamber and coupled to the vapor source, wherein the reaction vessel has an outlet to the vacuum chamber, and wherein the reaction vessel is configured to receive the vapor from the vapor source and to emit a portion of the received vapor into the vacuum chamber through the outlet; and
one or more sensors housed in the vacuum chamber, wherein the one or more sensors are configured to detect the vapor emitted through the outlet.

2. The system of claim 1, further comprising a valve configured to control an amount of the vapor received by the reaction vessel from the vapor source.

3. The system of claim 2, wherein the valve is configured to control the amount of the vapor in response to one or more control signals.

4. The system of claim 1, wherein the vapor source contains a vacuum-compatible material, and the vacuum-compatible material comprises selenium.

5. The system of claim 1, wherein the sensor comprises a microbalance, an ion gauge or a selenium rate monitor.

6. The system of claim 1, wherein the vapor source has a first pressure, the reaction vessel has a second pressure, and the vacuum chamber has a third pressure.

7. The system of claim 6, wherein the first pressure is greater than the second pressure and the second pressure is greater than the third pressure.

8. The system of claim 6, wherein the first pressure ranges from about 10⁺¹ to about 10⁻², the second pressure ranges from about 10⁻² to about 10⁻⁴, and the third pressure ranges from about 10⁻⁴ to about 10⁻⁶.

9. The system of claim 1, wherein the one or more sensors comprises a first sensor and a second sensor each housed in the vacuum chamber.

10. The system of claim 9, wherein the first sensor is positioned directly over the outlet and the second sensor is offset from the outlet.

11. The system of claim 9, further comprising a third sensor, wherein the third sensor is offset from the outlet.

12. The system of claim 9, wherein the first sensor and the second sensor are each offset from the outlet.

13. A method, the method comprising:
transferring, through a valve, a vapor from a high pressure zone to a medium pressure zone;
emitting, through an outlet, a portion of the transferred vapor from the medium pressure zone to a low pressure zone; and
detecting, by a sensor in the low pressure zone, the vapor emitted through the outlet,
wherein the medium pressure zone is a reaction vessel capable of housing a substrate.

14. The method of claim 13, further comprising:
developing a control signal, based on the vapor detected by the sensor; and
controlling the valve based on the control signal.

15. The method of claim 13, wherein controlling the valve based on the control signal comprises controlling a rate of transfer of the vapor from the high pressure zone to the medium pressure zone.

16. The method of claim 13, wherein the vapor comprises selenium.

17. The method of claim 13, wherein the sensor comprises a microbalance, an ion gauge or a selenium rate monitor.

18. The method of claim 13, further comprising:
generating the vapor in the high pressure zone; and
reacting the vapor in the medium pressure zone.

19. The method of claim 13, further comprising:
detecting, by a second sensor in the low pressure zone, the vapor emitted through the outlet; and
detecting, by a third sensor in the low pressure zone, the vapor emitted through the outlet.

20. (canceled)

21. A system, comprising:
a vacuum chamber;
a vapor source housed in the vacuum chamber, wherein the vapor source is configured to generate a vapor;
a reaction vessel housed in the vacuum chamber and coupled to the vapor source, wherein the reaction vessel is capable of housing a substrate and has an outlet to the vacuum chamber, and wherein the reaction vessel is configured to receive the vapor from the vapor source and to emit a portion of the received vapor into the vacuum chamber through the outlet; and
one or more sensors housed in the vacuum chamber, wherein the one or more sensors are configured to detect the vapor emitted through the outlet.
